(19) United States
(12) Patent Application Publication
(10) Pub. No.: US 2018/0019366 A1
(43) Pub. Date: Jan. 18, 2018

(54) SOLAR CELL, METHOD FOR MANUFACTURING SOLAR CELL, AND HEATING DEVICE USED THEREIN

(71) Applicant: Panasonic Intellectual Property Management Co., Ltd., Osaka (JP)

(72) Inventors: Naohiro HITACHI, Osaka (JP); Shigeharu TAIRA, Osaka (JP); Yayoi NAKATSUKA, Osaka (JP); Azumi UMEDA, Osaka (JP); Yuta SEKI, Osaka (JP); Shoji SATO, Osaka (JP)

(21) Appl. No.: 15/719,519

(22) Filed: Sep. 28, 2017

Related U.S. Application Data
(63) Continuation of application No. PCT/JP2016/000943, filed on Feb. 23, 2016.

(30) Foreign Application Priority Data
Mar. 31, 2015 (JP) 2015-071113

(51) Int. Cl. H01L 31/18; H01L 31/02; H01L 31/0224; H05B 3/00; H01L 31/068; H01L 31/075

(52) U.S. Cl. CPC H01L 31/1884; H01L 31/022433; H05B 3/0047; H01L 31/0201; H01L 31/022466; H01L 31/075; H01L 31/068

(57) ABSTRACT

A method for manufacturing a solar cell includes: providing an electrode layer containing thermosetting resin on at least one of a first main surface and a second main surface, located opposite to the first main surface, of a photoelectric conversion unit; heating the electrode layer by irradiation of infrared light; and producing an air stream around the photoelectric conversion unit during irradiation of infrared light. The irradiation of infrared light may include irradiation of first infrared light from a first emitter facing the first main surface; and irradiation of second infrared light from a second emitter facing the second main surface.

### RELATED APPLICATION

Priority is claimed to Japanese Patent Application No. 2015-071113, filed on Mar. 31, 2015, the entire content of which is incorporated herein by reference.

### BACKGROUND

### 1. Field of the Invention

The present invention relates to a solar cell, a method for manufacturing a solar cell, and a heating device used in the method.

### 2. Description of the Related Art

On a surface of a solar cell, an electrode is provided to derive generated electric power. For example, an electrode provided on a cell surface is formed by calcining silver paste printed on the surface.

### SUMMARY

It is desirable to provide a solar cell having higher output characteristics.

The present invention has been made in view of such a situation, and a purpose thereof is to provide a solar cell with improved output characteristics.

An embodiment of the present invention is a method for manufacturing a solar cell. The method includes: providing an electrode layer containing thermosetting resin on at least one of a first main surface and a second main surface, located opposite to the first main surface, of a photoelectric conversion unit; heating the electrode layer by irradiation of infrared light; and producing an air stream around the photoelectric conversion unit during irradiation of infrared light.

Another embodiment of the present invention is a heating device. The device is a heating device for heating thermosetting resin provided on a main surface of a photoelectric conversion unit and includes: a supporting portion that supports the photoelectric conversion unit in a standing state so that a main surface of the photoelectric conversion unit is provided along a vertical direction; a first emitter and a second emitter that are provided to face each other with the photoelectric conversion unit supported by the supporting portion therebetween and that emit infrared light toward the photoelectric conversion unit; and an exhaust port provided below the first emitter and the second emitter in the vertical direction. The exhaust port produces an air stream flowing in the vertical direction near the photoelectric conversion unit supported by the supporting portion.

Yet another embodiment of the present invention is a solar cell. The solar cell includes a power generation layer including a p-n junction or a p-i-n junction, a transparent conductive layer disposed on the power generation layer, and an electrode disposed on part of the transparent conductive layer. The transparent conductive layer includes a first portion positioned beneath the electrode, and a second portion different in crystallinity from the first portion.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a sectional view that shows the structure of a solar cell according to an embodiment;

FIG. 2 is a plan view that shows the structure of a light-receiving surface of the solar cell according to the embodiment;

FIG. 3 is a flowchart that shows a method for manufacturing the solar cell according to the embodiment;

FIG. 4 is a sectional view that schematically shows a manufacturing process of the solar cell;

FIG. 5 is a sectional view that schematically shows another manufacturing process of the solar cell;

FIG. 6 is a sectional view that schematically shows yet another manufacturing process of the solar cell;

FIG. 7 is a diagram that schematically shows the structure of a heating device used for manufacture of a solar cell;

FIG. 8 is a sectional view that schematically shows still yet another manufacturing process of the solar cell;

FIG. 9 is a flowchart that shows a method for manufacturing a solar cell according to a modification;

FIG. 10 is a sectional view that schematically shows a manufacturing process of the solar cell according to the modification; and

FIG. 11 is a sectional view that schematically shows another manufacturing process of the solar cell according to the modification.

### DETAILED DESCRIPTION

The invention will now be described by reference to the preferred embodiments. This does not intend to limit the scope of the present invention, but to exemplify the invention.

A general description will be given before the present invention is specifically described. Embodiments of the present invention relate to a solar cell and a method for manufacturing a solar cell. A solar cell comprises a power generation layer including a p-n junction or a p-i-n junction, a transparent conductive layer disposed on the power generation layer, and an electrode disposed on part of the transparent conductive layer. An electrode of the solar cell is formed by providing an electrode layer containing thermosetting resin and heating the electrode layer by irradiation of infrared light, and an air stream is provided during the irradiation of infrared light. In the present embodiment, by irradiation of infrared light with an air stream provided therearound, the electrode layer is locally heated while heat influence on a p-n junction or p-i-n junction in the power generation layer is restrained. Accordingly, degradation in power generation efficiency due to heat influence on a junction can be prevented, so that the output characteristics of the solar cell can be improved.

Hereinafter, a mode for carrying out the present invention will be described in detail with reference to the drawings. In the drawings, like reference characters designate like or corresponding elements, and the description thereof will not be repeated for brevity.

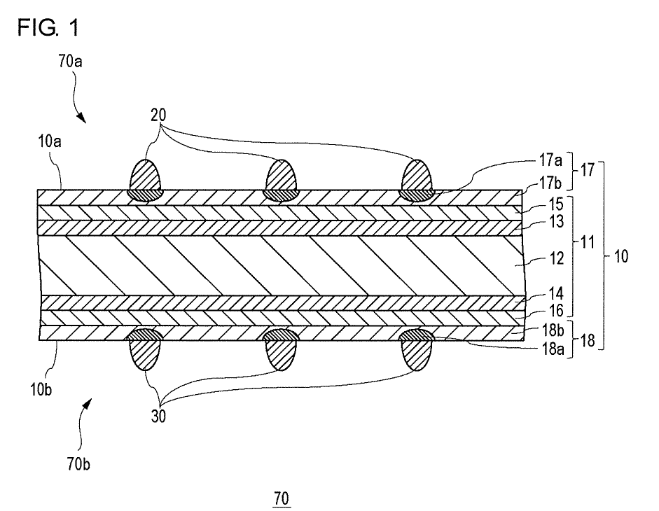

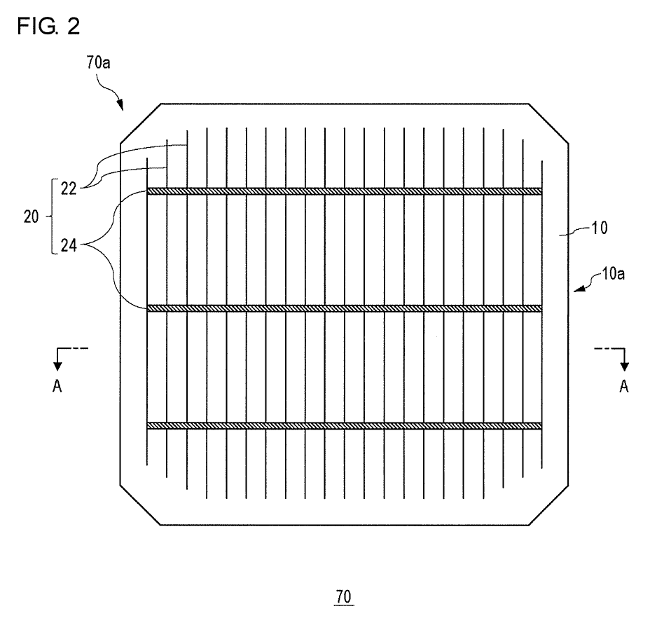

FIG. 1 is a sectional view that shows the structure of a solar cell 70 according to an embodiment and is taken along line A-A of FIG. 2, which will be described later.

The solar cell 70 comprises a photoelectric conversion unit 10, light-receiving surface electrodes 20, and back surface electrodes 30. The light-receiving surface electrodes 20 are disposed on a first main surface 10a of the photoelectric conversion unit 10, and the back surface electrodes 30 are disposed on a second main surface 10b of the photoelectric conversion unit 10. The light-receiving surface electrodes 20 and the back surface electrodes 30 are formed of a material containing a conductive substance, such as silver (Ag).

The first main surface 10a of the photoelectric conversion unit 10 is a main surface located on a light-receiving surface 70a side of the solar cell 70, and the second main surface 10b is a main surface located on a back surface 70b side of the solar cell 70 and opposite to the first main surface 10a. The light-receiving surface means a main surface on which sunlight is mainly incident in the solar cell 70 and is, more specifically, a surface on which most of the light provided to the photoelectric conversion unit 10 is incident.

The photoelectric conversion unit 10 comprises a power generation layer 11, a first transparent conductive layer 17, and a second transparent conductive layer 18. The power generation layer 11 is a layer that absorbs incident light to generate photovoltaic power and includes a p-n junction or a p-i-n junction. The power generation layer 11 includes a semiconductor substrate 12 formed of crystalline silicon, gallium arsenide (GaAs), or indium phosphide (InP), for example. In the present embodiment, an n-type monocrystalline silicon substrate is used as the semiconductor substrate 12.

The power generation layer 11 also includes a first i-type layer 13 and a first conductivity type layer 15, which are stacked on a main surface of the semiconductor substrate 12 on the light-receiving surface 70a side, and a second i-type layer 14 and a second conductivity type layer 16, which are stacked on another main surface of the semiconductor substrate 12 on the back surface 70b side. The first i-type layer 13 and second i-type layer 14 may be formed of intrinsic i-type amorphous silicon, for example. The first conductivity type layer 15 is formed of a p-type semiconductor material, such as p-type amorphous silicon doped with boron (B). Also, the second conductivity type layer 16 is formed of an n-type semiconductor material, such as n-type amorphous silicon doped with phosphorus (P). Accordingly, the power generation layer 11 of the present embodiment includes a p-i-n junction.

The first transparent conductive layer 17 is disposed upon the first conductivity type layer 15 and constitutes the first main surface 10a of the photoelectric conversion unit 10. Also, the second transparent conductive layer 18 is disposed upon the second conductivity type layer 16 and constitutes the second main surface 10b of the photoelectric conversion unit 10. The first transparent conductive layer 17 and second transparent conductive layer 18 may be formed of transparent conductive oxide (TCO), such as tin dioxide (SnO₂), zinc oxide (ZnO), indium tin oxide (ITO), or the like, doped with tin (Sn), antimony (Sb), fluorine (F), aluminum (Al), or the like. The first transparent conductive layer 17 and second transparent conductive layer 18 of the present embodiment are indium tin oxide layers.

The first transparent conductive layer 17 includes first portions 17a positioned immediately beneath the light-receiving surface electrodes 20, and a second portion 17b different from the first portions 17a. The first portions 17a and second portion 17b are formed of transparent conductive oxide of the same material but have structures different in crystallinity from each other. More specifically, the first portions 17a in contact with the light-receiving surface electrodes 20 have higher crystallinity and lower sheet resistance, compared to the second portion 17b. Such first portions 17a are formed when the light-receiving surface electrodes 20 are heated in the process of forming the light-receiving surface electrodes 20 and portions of the first transparent conductive layer 17 positioned immediately beneath the light-receiving surface electrodes 20 are also locally heated. Similarly, the second transparent conductive layer 18 includes first portions 18a positioned immediately beneath the back surface electrodes 30 and a second portion 18b having crystallinity different from that of the first portions 18a, and the sheet resistance of the first portions 18a is lower than that of the second portion 18b.

FIG. 2 is a plan view of the solar cell 70 according to the embodiment and shows the structure of the light-receiving surface 70a of the solar cell 70.

The light-receiving surface electrodes 20 include multiple finger electrodes 22 extending in parallel with each other, and three bus bar electrodes 24 extending perpendicularly to the finger electrodes 22. The finger electrodes 22 are formed on the first main surface 10a of the photoelectric conversion unit 10 on which light is mainly incident and hence are formed thin so as not to block light incident on the photoelectric conversion unit 10. The bus bar electrodes 24 connect the multiple finger electrodes 22 to each other. The bus bar electrodes 24 are formed appropriately thin so as not to block light incident on the photoelectric conversion unit 10 but are also formed appropriately wide so as to efficiently deliver electric power collected from the multiple finger electrodes 22.

As with the light-receiving surface electrodes 20, the back surface electrodes 30 also include multiple finger electrodes extending in parallel with each other, and three bus bar electrodes extending perpendicularly to the finger electrodes. However, since the main surface on the back surface 70b side is not a surface on which sunlight is mainly incident, a larger number of finger electrodes may be provided on the back surface 70b side, compared to the number of finger electrodes 22 on the light-receiving surface 70a side, so as to improve power collection efficiency.

There will now be described a method for manufacturing the solar cell 70.

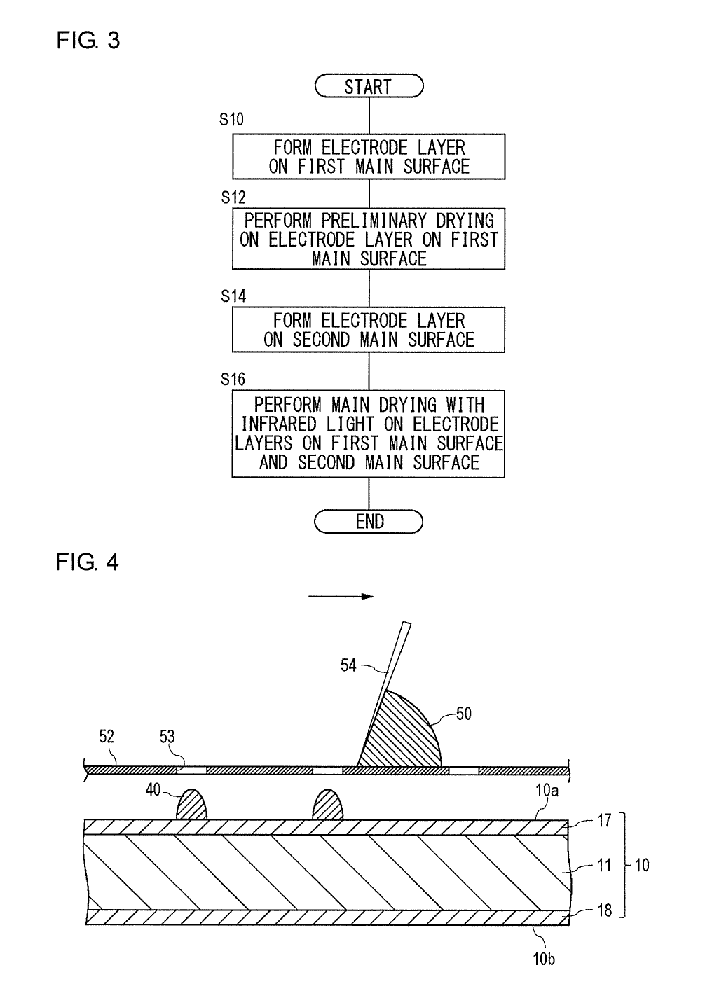

FIG. 3 is a flowchart that shows a method for manufacturing the solar cell 70 according to the embodiment. First, the photoelectric conversion unit 10 is prepared and an electrode layer is formed on the first main surface 10a of the photoelectric conversion unit 10 (S10), and the electrode layer thus formed on the first main surface 10a is then subjected to preliminary drying (S12). Thereafter, an electrode layer is also formed on the second main surface 10b of the photoelectric conversion unit 10 (S14), and the electrode layers formed on the first main surface 10a and the second main surface 10b are subjected to main drying with irradiation of infrared light (S16).

FIG. 4 is a sectional view that schematically shows a manufacturing process of the solar cell 70, which is the process of forming an electrode layer 40 on the first main surface 10a (S10). In the present embodiment, the electrode layer 40 is formed on the first main surface 10a by screen printing. Above the first main surface 10a, a screen plate 52 provided with opening patterns 53 is disposed, and conductive paste 50 on the screen plate 52 is extruded by a squeegee 54. Accordingly, the conductive paste 50 is applied onto the first main surface 10a at the positions corresponding to the opening patterns 53, thereby forming the electrode layer 40.

The conductive paste 50 is resin-type conductive paste obtained by including a conductive particulate filler, such as silver particles, in a binder made of a resin material. The conductive paste 50 of the present embodiment contains thermosetting resin, such as epoxy resin, as the binder, and silver (Ag) particles as the filler.

The electrode layer 40 is formed on the first main surface 10a and then subjected to preliminary drying. The electrode layer 40 after the preliminary drying is not completely hardened by the heating but is hardened to such an extent that the shape thereof hardly changes even when the photoelectric conversion unit 10 is transported or the first main surface 10a and the second main surface 10b are vertically inverted in a subsequent process. Therefore, it can be said that the “preliminary drying” and the “main drying”, in which the electrode layer 40 is completely hardened, are different in degree of hardening. For example, the preliminary drying may be performed by placing the photoelectric conversion unit 10 in an environment at a temperature (about 150 degrees C., for example) that is lower than a temperature required to completely harden the thermosetting resin (200 degrees C. or higher, for example). Also, the preliminary drying may be performed by irradiation of infrared light toward the photoelectric conversion unit 10, similarly to the “main drying” process, which will be described later with reference to FIG. 6.

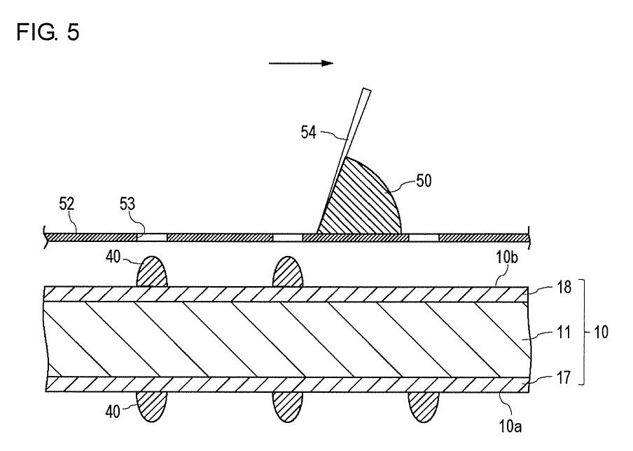

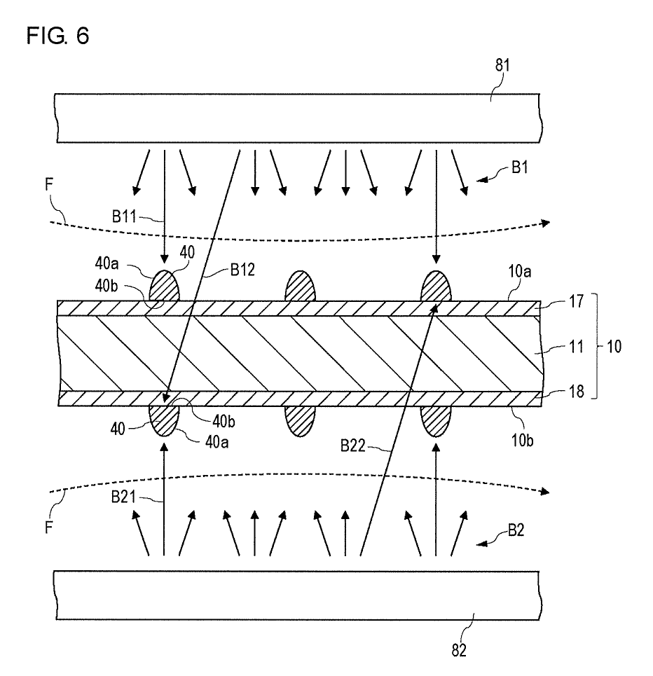

FIG. 5 is a sectional view that schematically shows another manufacturing process of the solar cell 70, which is the process of forming the electrode layer 40 on the second main surface 10b (S14). In FIG. 5, the photoelectric conversion unit 10 shown in FIG. 4 is inverted so that the electrode layer 40 can be formed on the second main surface 10b. As with the first main surface 10a, onto the second main surface 10b is applied the conductive paste 50 at the positions corresponding to the opening patterns 53 by screen printing, thereby forming the electrode layer 40 on the second main surface 10b. The screen plate 52 used here may be the same as that used in the printing on the first main surface 10a or may be different therefrom.

FIG. 6 is a sectional view that schematically shows yet another manufacturing process of the solar cell 70, which is the process of performing main drying on the electrode layers 40 on the first main surface 10a and second main surface 10b (S16). In the main drying, the electrode layers 40 are heated so that the thermosetting resin included therein is completely hardened. Accordingly, in the main drying, the electrode layers 40 are heated so that the temperature thereof reaches a temperature required to harden the thermosetting resin (200 degrees C. or higher, for example). In the present embodiment, the main drying is performed by heating the electrode layers 40 by irradiation of infrared light.

As shown in FIG. 6, on the both sides of the photoelectric conversion unit 10 are disposed a first emitter 81 and a second emitter 82 that emit infrared light. The first emitter 81 is disposed to face the first main surface 10a and emits first infrared light B1 that mainly travels toward the first main surface 10a. Also, the second emitter 82 is disposed to face the second main surface 10b and emits second infrared light B2 that mainly travels toward the second main surface 10b. Each of the first emitter 81 and second emitter 82 is an electrothermal emitter that electrically produces heat so as to emit infrared light, and may be constituted by a heater, such as a halogen heater, a carbon heater, and a ceramic heater, for example.

In a modification, one of the first emitter 81 and second emitter 82 may be a re-radiating emitter that absorbs infrared light to produce heat so as to emit infrared light. The re-radiating emitter is constituted by a member having high emissivity for infrared light, such as alumina (Al₂O₃), silicon carbide (SiC), or other ceramics, and titanium (Ti) or other metals. When the first emitter 81 is an electrothermal emitter and the second emitter 82 is a re-radiating emitter, the second emitter 82 absorbs first infrared light emitted by the first emitter 81 and emits second infrared light. Conversely, the first emitter 81 may be a re-radiating emitter, and the second emitter 82 may be an electrothermal emitter.

Each of the first emitter 81 and second emitter 82 emits infrared light having a wavelength with which the transmittance with respect to the semiconductor layer constituting the power generation layer 11 is high. Since the power generation layer 11 of the present embodiment is formed of silicon, it may be desirable to use an emitter that emits infrared light having a wavelength of about 1.3 μm or greater, which is less absorbed by silicon. Irradiation of infrared light having such a wavelength to the photoelectric conversion unit 10 allows the electrode layers 40 to selectively absorb the infrared light and be heated accordingly, and also prevents the power generation layer 11 from absorbing the infrared light and being heated.

Part of the infrared light emitted to the both sides of the photoelectric conversion unit 10 penetrates the photoelectric conversion unit 10 and travels toward parts of the electrode layer 40 in contact with the photoelectric conversion unit 10 (contact parts 40b). For example, the first infrared light B1 emitted by the first emitter 81 includes infrared light B11 traveling toward an exposed part 40a of the electrode layer 40 on the first main surface 10a, and also includes infrared light B12 traveling toward a contact part 40b, in contact with the second transparent conductive layer 18, of the electrode layer 40 on the second main surface 10b. Similarly, the second infrared light B2 emitted by the second emitter 82 includes infrared light B21 traveling toward an exposed part 40a of the electrode layer 40 on the second main surface 10b, and infrared light B22 traveling toward a contact part 40b, in contact with the first transparent conductive layer 17, of the electrode layer 40 on the first main surface 10a. Accordingly, both the exposed parts 40a and contact parts 40b of the electrode layer 40 on each of the first main surface 10a and the second main surface 10b are irradiated with infrared light.

During irradiation of infrared light, an air stream F is provided around the photoelectric conversion unit 10. Providing a stream of air around the photoelectric conversion unit 10 prevents high-temperature air heated by irradiation of infrared light from staying around the photoelectric conversion unit 10. In other words, the electrode layers 40 can be heated by radiation heat of infrared light, while heating of the power generation layer 11 by conductive heat via high-temperature air can be prevented by providing the air stream F. Thus, heating of the power generation layer 11 can be prevented in the main drying process using infrared light.

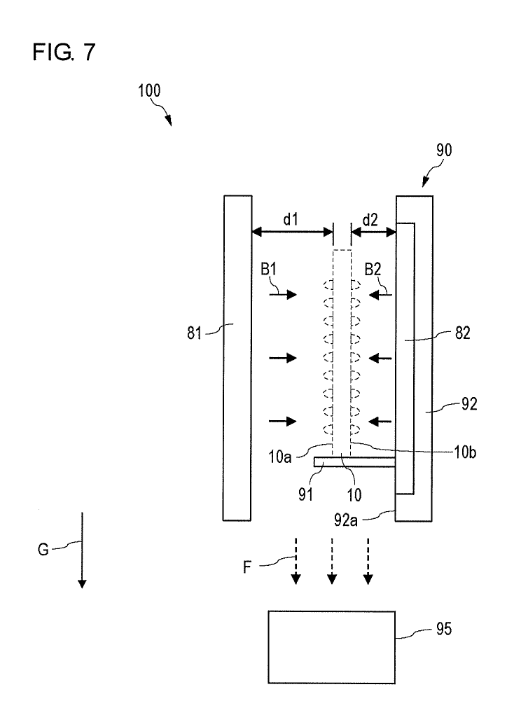

FIG. 7 is a diagram that schematically shows the structure of a heating device 100 used for manufacture of the solar cell 70. The heating device 100 is a device used to heat the electrode layers 40 with infrared light in the main drying process as shown in FIG. 6. The heating device 100 comprises the first emitter 81, the second emitter 82, a transport mechanism 90, and an exhaust port 95.

The transport mechanism 90 constitutes at least part of a transport system that carries, into the heating device 100, the photoelectric conversion unit 10 with the electrode layers 40 formed thereon and that carries, out of the heating device 100, the photoelectric conversion unit 10 after the electrode layers 40 thereof are dried. The transport mechanism 90 includes a supporting portion 91 for supporting the photoelectric conversion unit 10, and a body portion 92 to which the supporting portion 91 is fixed. On a main surface 92a of the body portion 92, the second emitter 82 is provided.

The supporting portion 91 supports the photoelectric conversion unit 10 standing thereon. More specifically, the supporting portion 91 supports the photoelectric conversion unit 10 so that the first main surface 10a or the second main surface 10b of the photoelectric conversion unit 10 is provided along a vertical direction G, which is the direction of gravitational force. The supporting portion 91 also supports the photoelectric conversion unit 10 so that the photoelectric conversion unit 10 is positioned closer to the second emitter 82 provided on the main surface 92a of the body portion 92. More specifically, the supporting portion 91 supports the photoelectric conversion unit 10 so that a distance d2 between the photoelectric conversion unit 10 and the second emitter 82 is several centimeters or less, or so that the photoelectric conversion unit 10 and the second emitter 82 become close to be in contact with each other.

The first emitter 81 is disposed to face the second emitter 82 so that directions away from each other intersect the vertical direction G. Also, the first emitter 81 and the second emitter 82 are provided to face each other with the photoelectric conversion unit 10 supported by the supporting portion 91 therebetween. Accordingly, the first emitter 81 is disposed so as to emit the first infrared light B1 toward the second emitter 82, and the second emitter 82 is disposed so as to emit the second infrared light B2 toward the first emitter 81.

The first emitter 81 is disposed close to the photoelectric conversion unit 10 supported by the supporting portion 91 so that the photoelectric conversion unit 10 is efficiently irradiated with infrared light. For example, the first emitter 81 is disposed so that a distance d1 between the first emitter 81 and the photoelectric conversion unit 10 is about several centimeters, preferably about 4-5 centimeters. As described previously, the first emitter 81 is an electrothermal emitter constituted by a heater, such as a ceramic heater, for example.

The second emitter 82 is constituted by an electrothermal emitter or a re-radiating emitter. When the second emitter 82 is a re-radiating emitter, it can be formed by, for example, making the main surface 92a of the body portion 92 of a material having high emissivity for infrared light (ceramics, or metals, such as titanium). The second emitter 82 of re-radiating type can be formed by covering the main surface 92a of the body portion 92 with a material having high emissivity for infrared light or by embedding such a material in a recess provided on the main surface 92a, for example. Also, by forming the entire body portion 92 of a material having high emissivity, the body portion 92 may be provided with the function of the second emitter 82.

The exhaust port 95 is provided vertically below the first emitter 81 and the second emitter 82. Through the exhaust port 95, air within the heating device 100 is discharged to the outside, thereby producing the air stream F flowing in the vertical direction G around the photoelectric conversion unit 10 supported by the supporting portion 91. This prevents high-temperature air staying around the photoelectric conversion unit 10. Through the exhaust port 95, a gas component of a solvent evaporated from the thermosetting resin in the process of heating the electrode layers 40, for example, is also discharged outside the heating device 100.

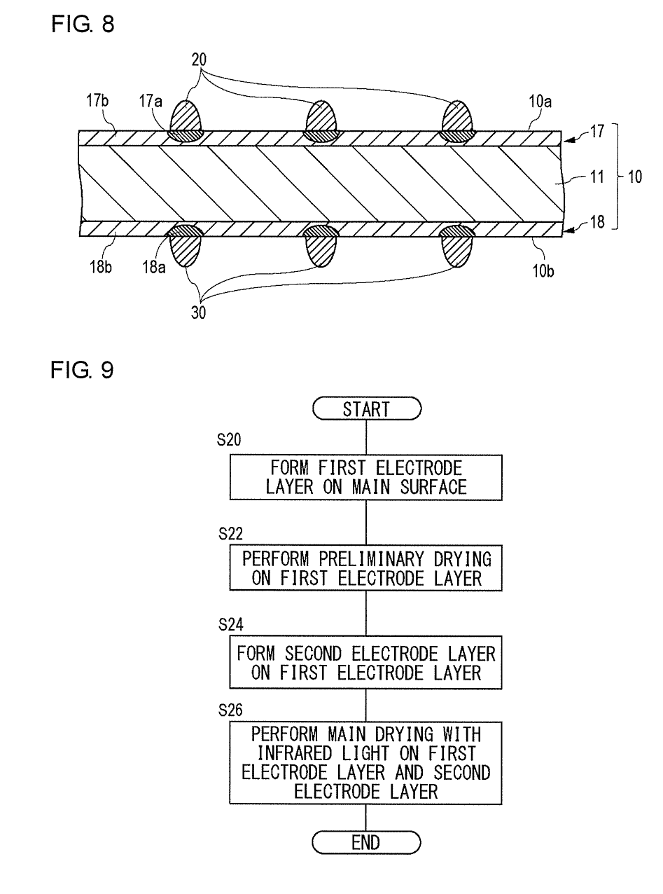

FIG. 8 is a sectional view that schematically shows still yet another manufacturing process of the solar cell 70, showing the photoelectric conversion unit 10 after the main drying process (S16). The electrode layers 40 are hardened in the main drying process with irradiation of infrared light, so that the electrode layer 40 on the first main surface 10a becomes the light-receiving surface electrodes 20, and the electrode layer 40 on the second main surface 10b becomes the back surface electrodes 30. Also, in the first transparent conductive layer 17 are formed the first portions 17a positioned immediately beneath the light-receiving surface electrodes 20, and the second portion 17b different in crystallinity from the first portions 17a. Similarly, in the second transparent conductive layer 18 are formed the first portions 18a positioned immediately beneath the back surface electrodes 30, and the second portion 18b different in crystallinity from the first portions 18a.

In the first transparent conductive layer 17, the first portions 17a have higher crystallinity and lower sheet resistance than the second portion 17b therearound. The first portions 17a are formed by locally heating, with the electrode layer 40 heated by irradiation of infrared light, portions of the first transparent conductive layer 17 positioned immediately beneath the electrode layer 40. After the local heating, the first transparent conductive layer 17 is provided with improved crystallinity and lower sheet resistance compared to before the heating. Thus, the resistance of the first portions 17a of the first transparent conductive layer 17 in contact with the light-receiving surface electrodes 20 is lowered, thereby improving power collection efficiency of the light-receiving surface electrodes 20. Also, the first portions 18a of the second transparent conductive layer 18 positioned immediately beneath the back surface electrodes 30 are formed in the same way, with the electrode layer 40 locally heated. Accordingly, contact resistance between the second transparent conductive layer 18 and the back surface electrodes 30 is lowered, thereby improving power collection efficiency of the back surface electrodes 30.

There will now be described effects provided by the solar cell 70, the method for manufacturing the solar cell 70, and the heating device 100 according to the present embodiment.

According to the present embodiment, since the electrode layers 40 are heated by infrared light, temperature rise in the power generation layer 11 can be restrained, compared to the case of heating the electrode layers 40 with high-temperature air. Especially, by using infrared light having a wavelength with which the transmittance with respect to silicon constituting the power generation layer 11 is high, heating of the power generation layer 11 due to absorption of infrared light can be effectively prevented. This prevents the case where a p-n junction or a p-i-n junction in the power generation layer 11 is affected by the heat and the power generation efficiency of the photoelectric conversion unit 10 is lowered accordingly. Therefore, the present embodiment can improve the output characteristics of the solar cell 70.

Also, according to the present embodiment, since both the first main surface 10a and the second main surface 10b of the photoelectric conversion unit 10 are irradiated with infrared light, the electrode layers 40 can be effectively heated. Especially, since infrared light penetrates the power generation layer 11, besides the exposed parts 40a, the contact parts 40b of the electrode layers 40 in contact with the photoelectric conversion unit 10 can also be irradiated with infrared light. This can efficiently heat the electrode layers 40 from the both sides, thereby hardening the electrode layers 40 in a shorter time. Therefore, the electrode layers 40 can be sufficiently heated, while heat influence on the power generation layer 11 is restrained.

Also, according to the present embodiment, since the light-receiving surface electrodes 20 and the back surface electrodes 30 are provided with the finger electrodes and the bus bar electrodes, the electrode layers 40 can be heated more sufficiently while heat influence on the power generation layer 11 is restrained. Part of the infrared light emitted to the light-receiving surface electrodes 20 is incident on the photoelectric conversion unit 10 through spaces between the finger electrodes of the light-receiving surface electrodes 20 and penetrates the photoelectric conversion unit 10 to travel toward parts of the back surface electrodes 30 in contact with the photoelectric conversion unit 10. Similarly, part of the infrared light emitted to the back surface electrodes 30 is incident on the photoelectric conversion unit 10 through spaces between the finger electrodes of the back surface electrodes 30 and penetrates the photoelectric conversion unit 10 to travel toward parts of the light-receiving surface electrodes 20 in contact with the photoelectric conversion unit 10. If the back surface electrodes are configured to cover substantially the entire power generation layer 11, infrared light emitted to the back surface electrodes will be blocked by the back surface electrodes and unable to reach the parts of the light-receiving surface electrodes 20 in contact with the photoelectric conversion unit 10. In this case, it may be unable to sufficiently heat the electrode layer. Therefore, when the power generation layer 11 is formed with the semiconductor substrate 12 made of crystalline silicon or the like and when electrodes are formed by applying conductive paste on the both sides of the power generation layer 11, both the light-receiving surface electrodes 20 and the back surface electrodes 30 may be preferably configured to comprise finger electrodes and bus bar electrodes, as described in the present embodiment.

Also, according to the present embodiment, since an air stream is provided around the photoelectric conversion unit 10 during irradiation of infrared light, heating of the power generation layer 11 by high-temperature air staying around the photoelectric conversion unit 10 can be prevented. Further, by providing an air stream flowing vertically downward from the photoelectric conversion unit 10 in a standing state, a gas component that is heavier than air, such as a solvent evaporated from the electrode layers 40, can be effectively discharged. Also, effectively discharging a solvent component prompts evaporation of the solvent included in the electrode layers 40, thereby reducing the time required to harden the electrode layers 40.

Also, according to the present embodiment, since the photoelectric conversion unit 10 is placed in a standing state, the situation can be prevented in which dust or the like falls onto a main surface of the photoelectric conversion unit 10 and adheres thereto during the heating process. Also, by forming an air stream flowing vertically downward, the situation can be prevented in which trash or dust that has entered the heating device 100 is stirred up and adheres to the photoelectric conversion unit 10.

Also, according to the present embodiment, the electrode layers 40 are locally heated so as to improve the crystallinity and lower the sheet resistance of the first portions 17a of the first transparent conductive layer 17 positioned beneath the light-receiving surface electrodes 20 and the first portions 18a of the second transparent conductive layer 18 beneath the back surface electrodes 30. This lowers the contact resistance between the light-receiving surface electrodes 20 and the first transparent conductive layer 17 and between the back surface electrodes 30 and the second transparent conductive layer 18. Accordingly, power collection efficiency of the light-receiving surface electrodes 20 and back surface electrodes 30 can be improved, so that the output characteristics of the solar cell 70 can also be improved.

An aspect of the present embodiment is a method for manufacturing a solar cell 70. The method comprises:

providing an electrode layer 40 containing thermosetting resin on at least one of a first main surface 10a and a second main surface 10b, located opposite to the first main surface 10a, of a photoelectric conversion unit 10;

heating the electrode layer 40 by irradiation of infrared light; and

producing an air stream F around the photoelectric conversion unit 10 during the irradiation of infrared light.

The photoelectric conversion unit 10 may comprise a semiconductor substrate 12, and the electrode layer 40 may comprise a plurality of finger electrodes extending in parallel with each other and a bus bar electrode extending perpendicularly to the finger electrodes.

The irradiation of infrared light may include:

irradiation of first infrared light B1 from a first emitter 81 facing the first main surface 10a; and

irradiation of second infrared light B2 from a second emitter 82 facing the second main surface 10b.

The first emitter 81 and the second emitter 82 may electrically produce heat to emit infrared light.

The first emitter 81 may electrically produce heat to emit the first infrared light B1, and

the second emitter 82 may absorb the first infrared light B1 to produce heat and emit the second infrared light B2.

The irradiation of infrared light may be performed in a state where the photoelectric conversion unit 10 is standing so that the first main surface 10a and the second main surface 10b are provided along a vertical direction G.

The producing an air stream F may be performed so that the air stream F flows in the vertical direction G toward an exhaust port 95 provided below the photoelectric conversion unit 10.

The photoelectric conversion unit 10 may have a structure in which the first main surface 10a, a first transparent conductive layer 17, a power generation layer 11 including a p-n junction or a p-i-n junction, a second transparent conductive layer 18, and the second main surface 10b are stacked in this order, and

the method for manufacturing the solar cell 70 may further comprise locally heating, with the electrode layer 40 heated by irradiation of infrared light, part of the first transparent conductive layer 17 or the second transparent conductive layer 18 positioned beneath the electrode layer.

Another aspect is a heating device 100. The heating device 100 is used for heating thermosetting resin provided on a main surface of a photoelectric conversion unit 10, and the heating device 100 comprises:

a supporting portion 91 that supports the photoelectric conversion unit 10 in a standing state so that the main surface of the photoelectric conversion unit 10 is provided along a vertical direction G;

a first emitter 81 and a second emitter 82 that are provided to face each other with the photoelectric conversion unit 10 supported by the supporting portion 91 therebetween and that emit infrared light toward the photoelectric conversion unit 10; and

an exhaust port 95 provided below the first emitter 81 and the second emitter 82 in the vertical direction G.

The exhaust port 95 produces an air stream F flowing in the vertical direction G near the photoelectric conversion unit 10 supported by the supporting portion 91.

Yet another aspect is a solar cell 70. The solar cell 70 comprises:

a power generation layer 11 including a p-n junction or a p-i-n junction;

a transparent conductive layer (a first transparent conductive layer 17, a second transparent conductive layer 18) provided on the power generation layer 11; and

an electrode (a light-receiving surface electrode 20, a back surface electrode 30) provided on part of the transparent conductive layer (first transparent conductive layer 17, second transparent conductive layer 18).

The transparent conductive layer (first transparent conductive layer 17, second transparent conductive layer 18) includes a first portion 17a, 18a positioned beneath the electrode (light-receiving surface electrode 20, back surface electrode 30), and a second portion 17b, 18b different in crystallinity from the first portion 17a, 18a.

The first portion 17a, 18a may have lower resistivity than the second portion 17b, 18b.

The present invention has been described with reference to the aforementioned embodiment. However, the present invention is not limited thereto and also includes a form resulting from appropriate combination or replacement of the configurations in the embodiment.

### (Modification)

FIG. 9 is a flowchart that shows a method for manufacturing the solar cell 70 according to a modification. In the manufacturing method according to the modification, a first electrode layer is formed on a main surface of the photoelectric conversion unit 10 (S20), the first electrode layer is subjected to preliminary drying (S22), a second electrode layer is formed on the first electrode layer after the preliminary drying (S24), and the first electrode layer and the second electrode layer are subjected to main drying with irradiation of infrared light (S26). The present modification differs from the embodiment set forth above in that multiple electrode layers are stacked so as to form the light-receiving surface electrodes 20 or the back surface electrodes 30. In the following, the modification will be described mainly for the differences from the aforementioned embodiment.

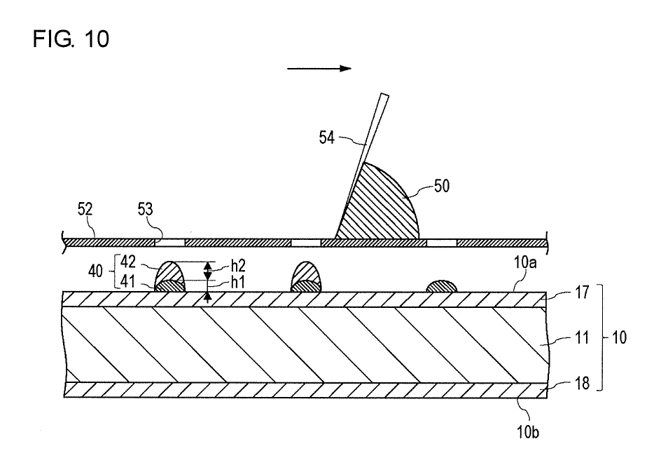

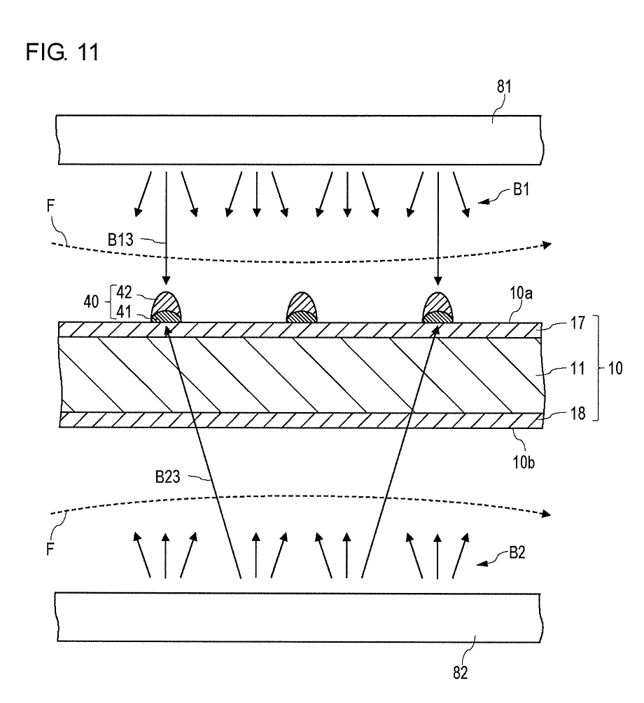

FIG. 10 is a sectional view that schematically shows a manufacturing process of the solar cell 70 according to the modification, which is the process of forming a second electrode layer 42 on a first electrode layer 41 (S24). Also, FIG. 10 shows the case where the first electrode layer 41 and the second electrode layer 42 are formed on the first main surface 10a. The first electrode layer 41 is formed on the first main surface 10a in the same way as in the process of S10 in the aforementioned embodiment and is then subjected to preliminary drying in the same way as in the process of S12.

The second electrode layer 42 is formed on the first electrode layer 41. The electrode layers are formed so that the thickness h2 of the second electrode layer 42 is greater than the thickness h1 of the first electrode layer 41. The thickness of the first electrode layer 41 or the second electrode layer 42 may be adjusted by changing the printing speed of the screen printing or changing the area or the thickness of the opening pattern 53 of the screen plate 52 to be used.

The conductive paste 50 used for printing of the first electrode layer 41 and the second electrode layer 42 may be of the same kind or may be of different kinds. If different kinds of the conductive paste 50 is used, it may be desirable to use, for the first electrode layer 41, a material that has smaller contact resistance with respect to the first transparent conductive layer 17 and higher adhesion to the first transparent conductive layer 17, compared to the material of the second electrode layer 42. Meanwhile, it may be preferable to use, for the second electrode layer 42, a material that has smaller bulk resistance than the material of the first electrode layer 41.

FIG. 11 is a sectional view that schematically shows another manufacturing process of the solar cell 70 according to the modification, which is the process of performing main drying with infrared light on the first electrode layer 41 and the second electrode layer 42 (S26). As shown in FIG. 11, the first electrode layer 41 and the second electrode layer 42 are irradiated with infrared light emitted by the first emitter 81 and the second emitter 82 disposed on the both sides of the photoelectric conversion unit 10. The second electrode layer 42 exposed above the first transparent conductive layer 17 is mainly irradiated with the first infrared light B1 (infrared light B13, for example) emitted by the first emitter 81. Meanwhile, the first electrode layer 41 close to the first transparent conductive layer 17 is mainly irradiated with the second infrared light B2 (infrared light B23, for example) emitted by the second emitter 82.

With regard to the first electrode layer 41, since the first electrode layer 41 is formed thinner than the second electrode layer 42 and is subjected to preliminary drying in the previous process, the time required for main drying is shorter and the temperature is more likely to rise, compared to the second electrode layer 42. Accordingly, the second electrode layer 42 is heated by infrared light that the second electrode layer 42 itself absorbs and also heated by the neighboring first electrode layer 41. By heating the second electrode layer 42 using both the infrared light and the first electrode layer 41, the rate of temperature rise in the second electrode layer 42 can be increased, and the time required for main drying can be reduced. Therefore, heat influence on the power generation layer 11 can be reduced in the main drying process.

In the present modification, since the electrode layer 40 is formed as two-layer structure, the drying process is increased compared to the case where the electrode layer 40 is formed as a single layer. However, by reducing the thickness of the first electrode layer 41, the heating time required for preliminary drying after the first electrode layer 41 is formed can be significantly reduced. Further, the time required for main drying after the second electrode layer 42 is formed can also be reduced compared to the main drying process in the aforementioned embodiment. Consequently, the heat influence on the power generation layer 11 can be further reduced.

Also, in the present modification, by using different materials for the first electrode layer 41 and the second electrode layer 42, the properties of the light-receiving surface electrodes 20 and the back surface electrodes 30 can be improved. For the first electrode layer 41, by using a material having high adhesion to the transparent conductive layer, an electrode that is less likely to peel off can be formed, thereby improving the durability of the solar cell 70. Also, by using, for the first electrode layer 41, a material having small contact resistance with respect to the transparent conductive layer, the efficiency of collecting power from the transparent conductive layer can be improved. Further, for the second electrode layer 42, by using a material having small bulk resistance, the conductivity of the light-receiving surface electrodes 20 and the back surface electrodes 30 can be improved, thereby improving the output characteristics of the solar cell 70.

Although the present modification describes the process of forming the electrode layer 40 on the first main surface 10a, the same process may be used to form the electrode layer 40 on the second main surface 10b. In this case, after the first electrode layer 41 and the second electrode layer 42 on the first main surface 10a are subjected to the main drying with infrared light, the first electrode layer 41 may be printed on the second main surface 10b and subjected to preliminary drying, the second electrode layer 42 may be then formed upon the first electrode layer 41 on the second main surface 10b, and the first electrode layer 41 and the second electrode layer 42 on the second main surface 10b may be subjected to main drying with infrared light. Alternatively, after the first electrode layer 41 and the second electrode layer 42 are formed on the first main surface 10a and subjected to preliminary drying, the first electrode layer 41 and the second electrode layer 42 may also be formed on the second main surface 10b, and both the electrode layers 40 on the first main surface 10a and the second main surface 10b may be subjected to main drying with infrared light.

Although the electrode layer 40 is structured to have two layers in the present modification, the electrode layer 40 may be structured to have three or more layers in another modification. In this case, the top electrode layer may be desirably thicker than the other electrode layers. Also, infrared light may be desirably used at least in the process of drying the thick top electrode layer.

In the method for manufacturing the solar cell 70 according to an aspect,

the providing an electrode layer 40 may include:

providing a first electrode layer 41 containing thermosetting resin on at least one of the first main surface 10a and the second main surface 10b; and

providing a second electrode layer 42 containing thermosetting resin on the first electrode layer 41 after heating the first electrode layer 41.

At least the second electrode layer 42 may be heated by irradiation of infrared light.

The photoelectric conversion unit 10 may have a structure in which the first main surface 10a, a first transparent conductive layer 17, a power generation layer 11 including a p-n junction or a p-i-n junction, a second transparent conductive layer 18, and the second main surface 10b are stacked in this order,

the first electrode layer 41 may be formed of a material having smaller contact resistance with respect to the first transparent conductive layer 17 or the second transparent conductive layer 18 than the second electrode layer 42, and

the second electrode layer 42 may be formed of a material having smaller bulk resistance than the first electrode layer 41.

In the embodiment and modification described above, after the electrode layer 40 on the first main surface 10a of the photoelectric conversion unit 10 is formed, the electrode layer 40 on the second main surface 10b is formed. In another modification, the order may be reversed, so that, after the electrode layer 40 on the second main surface 10b is formed, the electrode layer on the first main surface 10a may be formed.

In the embodiment and modification described above, the electrode layers 40 are formed by screen printing. In another modification, the electrode layers 40 may be formed using another well-known printing technique, such as offset printing, pad printing, relief printing, and intaglio printing.

It should be understood that the invention is not limited to the above-described embodiment, but may be modified into various forms on the basis of the spirit of the invention. Additionally, the modifications are included in the scope of the invention.

1. A method for manufacturing a solar cell, comprising:
providing an electrode layer containing thermosetting resin on at least one of a first main surface and a second main surface, located opposite to the first main surface, of a photoelectric conversion unit;
heating the electrode layer by irradiation of infrared light; and
producing an air stream around the photoelectric conversion unit during the irradiation of infrared light.

2. The method for manufacturing a solar cell according to claim 1, wherein
the photoelectric conversion unit comprises a semiconductor substrate, and the electrode layer comprises a plurality of finger electrodes extending in parallel with each other and a bus bar electrode extending perpendicularly to the finger electrodes, and wherein
the irradiation of infrared light includes:
irradiation of first infrared light from a first emitter facing the first main surface; and
irradiation of second infrared light from a second emitter facing the second main surface.

3. The method for manufacturing a solar cell according to claim 2, wherein the first emitter and the second emitter electrically produce heat to emit the infrared light.

4. The method for manufacturing a solar cell according to claim 2, wherein:
the first emitter electrically produces heat to emit the first infrared light; and
the second emitter absorbs the first infrared light to produce heat and emits the second infrared light.

5. The method for manufacturing a solar cell according to claim 1, wherein the irradiation of infrared light is performed in a state where the photoelectric conversion unit is standing so that the first main surface and the second main surface are provided along a vertical direction.

6. The method for manufacturing a solar cell according to claim 1, wherein the producing an air stream is performed so that the air stream flows in a vertical direction toward an exhaust port provided below the photoelectric conversion unit.

7. The method for manufacturing a solar cell according to claim 1, wherein
the providing an electrode layer includes:
providing a first electrode layer containing thermosetting resin on at least one of the first main surface and the second main surface; and
providing a second electrode layer containing thermosetting resin on the first electrode layer after heating the first electrode layer, and wherein
at least the second electrode layer is heated by the irradiation of infrared light.

8. The method for manufacturing a solar cell according to claim 7, wherein:
the photoelectric conversion unit has a structure in which the first main surface, a first transparent conductive layer, a power generation layer including a p-n junction or a p-i-n junction, a second transparent conductive layer, and the second main surface are stacked in this order;
the first electrode layer is formed of a material having smaller contact resistance with respect to the first transparent conductive layer or the second transparent conductive layer than the second electrode layer; and
the second electrode layer is formed of a material having smaller bulk resistance than the first electrode layer.

9. The method for manufacturing a solar cell according to claim 1, wherein:
the photoelectric conversion unit has a structure in which the first main surface, a first transparent conductive layer, a power generation layer including a p-n junction or a p-i-n junction, a second transparent conductive layer, and the second main surface are stacked in this order; and
the method for manufacturing further comprises locally heating, with the electrode layer heated by the irradiation of infrared light, part of the first transparent conductive layer or the second transparent conductive layer positioned beneath the electrode layer.

10. A heating device for heating thermosetting resin provided on a main surface of a photoelectric conversion unit, the heating device comprising:
a supporting portion that supports the photoelectric conversion unit in a standing state so that a main surface of the photoelectric conversion unit is provided along a vertical direction;
a first emitter and a second emitter that are provided to face each other with the photoelectric conversion unit supported by the supporting portion therebetween and that emit infrared light toward the photoelectric conversion unit; and
an exhaust port provided below the first emitter and the second emitter in the vertical direction, the exhaust port producing an air stream flowing in the vertical direction near the photoelectric conversion unit supported by the supporting portion.

11. A solar cell, comprising:
a power generation layer including a p-n junction or a p-i-n junction;
a transparent conductive layer provided on the power generation layer; and
an electrode provided on part of the transparent conductive layer, wherein
the transparent conductive layer includes a first portion positioned beneath the electrode, and a second portion different in crystallinity from the first portion.

12. The solar cell of claim 11, wherein the first portion has lower resistivity than the second portion.
